(19) United States
(12) Patent Application Publication
(10) Pub. No.: US 2011/0216503 A1
(43) Pub. Date: Sep. 8, 2011

(54) ELECTRONIC EQUIPMENT HOUSING

(76) Inventor: Shane Ramodien, Wahroonga (AU)

(21) Appl. No.: 13/128,802

(22) PCT Filed: Jan. 6, 2010
(86) PCT No.: PCT/AU10/00010

§ 371 Date: May 11, 2011

(30) Foreign Application Priority Data
Jan. 8, 2009 (AU) 2009900097

(51) Int. Cl. H05K 7/20; B65D 85/00

(52) U.S. Cl. 361/691; 206/320

(57) ABSTRACT

An electronic equipment housing (1000) comprises a housing body (300) comprising a conditioning unit (200) housing an air conditioner (210) and an equipment unit (100) adapted to house electrical equipment. A housing plenum (400) is mounted on top of the lower housing body (300), so as to cover and engage the equipment unit (100). The housing plenum (400) has at least one aperture (430) formed in the lower surface (450), wherein the aperture (430) is adapted to allow air to pass from the housing plenum (400) directly into the equipment unit (100) and wherein the housing plenum (400) is in fluid communication with the air conditioner (210). A duct arrangement (500) provides fluid communication between the equipment unit (100) and the air conditioner (210), wherein the duct arrangement (500) is adapted to return air from the equipment unit (100) to the air conditioner (210).

### FIELD OF THE INVENTION

The present invention relates to electronic equipment housing for controlling the environment for electronic equipment such as switchgear or computer servers.

### BACKGROUND

There are various types and sizes of equipment units used for housing electronics equipment, such as switchgear and computer servers. As an example, a standard 42U server rack cabinet has a height of 2025 mm, width 600 mm and depth of 1050 mm. The electronic equipment housed in these equipment units can generate a substantial amount of heat. Heat does dissipate to some extent within the equipment unit, and dissipate into the room in which the equipment unit sits, but this process is less than ideal. If the equipment is operating beyond its recommended temperature range, the electronics equipment can become operationally unreliable, system performance may be compromised, or system failure may result.

Furthermore, in many corporate IT departments and data centres, a room will be allocated to house a battery of such equipment units. The amount of heat generated within the equipment room increases substantially, and the effective operating temperature can be too high, and difficult to control. Conditions can be uncomfortable for staff when working in the equipment room.

One approach is to provide a supplementary stand-alone air conditioner within the equipment room. This provides cooling for the room and equipment, but more directly cools the room rather than the equipment. Another approach is to supplement the actual building's air conditioning system to provide additional cooling to the equipment room in question. This inevitably involves changing or supplementing the building's HVAC infrastructure and, consequently, is very likely to require approval, especially if the premises are leased rather than owned. Also, it may not be physically possible to deliver the required cooling to the equipment room due to infrastructure constraints.

Various configurations of fan units or air conditioning units are available that are intended to be housed within an equipment unit, but existing solutions do not adequately address the challenges of safe and reliable operation of equipment within the equipment unit. As an example, inadequate control of condensation created by operation of a built-in air conditioner can compromise equipment operation.

### OBJECT OF THE INVENTION

It is an object of the present invention to substantially overcome or at least ameliorate one or more of the above disadvantages, or to provide a useful alternative.

### SUMMARY OF THE INVENTION

The present invention provides an electronic equipment housing comprising:

a lower housing body comprising a conditioning unit and an equipment unit, the conditioning unit housing an air conditioner and the equipment unit being adapted to house electrical equipment;

an upper housing plenum mounted on top of the lower housing body, so as to cover and engage the equipment unit, the housing plenum having an upper surface and a lower surface and at least one aperture formed in the lower surface, wherein the aperture is adapted to allow air to pass from the housing plenum directly into the equipment unit and wherein the housing plenum is in fluid communication with the air conditioner; and

a duct arrangement providing fluid communication between the equipment unit and the air conditioner, wherein the duct arrangement is adapted to return air from the equipment unit to the air conditioner;

wherein the air conditioner is adapted to supply conditioned air under positive pressure into the housing plenum, resulting in the flow of conditioned air into the equipment unit via the aperture.

Preferably, the at least one aperture is an elongate slot. Further preferably, the elongate slot is arranged adjacent to a peripheral wall of the equipment unit. Further preferably, the elongate slot is part of an array including two pairs of parallel elongate slots.

In a preferred embodiment, the equipment unit has four peripheral walls and each elongate slot extends substantially parallel to and adjacent to one of the peripheral walls of the equipment unit.

Preferably, the housing plenum is mounted so as to cover and engage both the equipment unit and the conditioning unit.

The electronic equipment housing preferably comprises multiple equipment units. Further preferably, the housing plenum covers and engages all of the equipment units.

In a preferred embodiment, the housing plenum is modular and formed from multiple plenum units and wherein additional plenum units and additional equipment units are adapted to be added to the electronic equipment housing to increase the storage capacity of the electronic equipment housing.

Preferably, the plenum units are provided with elongate ports, such that the elongate ports of adjacent plenum units align to allow fluid communication between the adjacent plenum units.

Optionally, the housing plenum further includes outlet vents for venting conditioned air from the housing plenum.

In a preferred embodiment, electronic equipment is arranged in the equipment unit and multiple said apertures direct conditioned air into the equipment unit such that the conditioned air is directed down walls of the equipment unit in peripheral air curtains around the electronic equipment in the equipment unit.

In a preferred embodiment, electronic equipment is arranged in the equipment unit and the duct arrangement has inlets positioned directly proximate to outlets for air exhausted from the electronic equipment so that diffusion of air exhausted from the electronic equipment throughout the equipment unit is minimised

### BRIEF DESCRIPTION OF THE DRAWINGS

Preferred embodiments of the invention will now be described with reference to the accompanying drawings, in which:

FIG. 1 depicts an electronic equipment housing according to the present invention;

FIG. 2 is a vertical cross-sectional view of the electronic equipment housing depicted in FIG. 1;

FIG. 3 is a horizontal cross-sectional view through the housing plenum of the electronic equipment housing of FIG. 1;

FIG. 4 is a cross-sectional view of the conditioning unit of the electronic equipment housing of FIG. 1;

FIG. 5 is a schematic representation of air circulation patterns within the electronic equipment housing;

FIG. 6 is a schematic representation of air circulation patterns within the duct arrangement of the electronic equipment housing;

FIG. 7 is a schematic representation of an alternative embodiment of the housing plenum of the electronic equipment housing;

FIG. 8 is a schematic representation of a modular electronic equipment housing;

FIG. 9 is a schematic representation of an embodiment of a high-capacity electronic equipment housing; and

FIG. 10 is a partially transparent view of an embodiment of the electronic equipment housing.

### DETAILED DESCRIPTION OF THE PREFERRED EMBODIMENTS

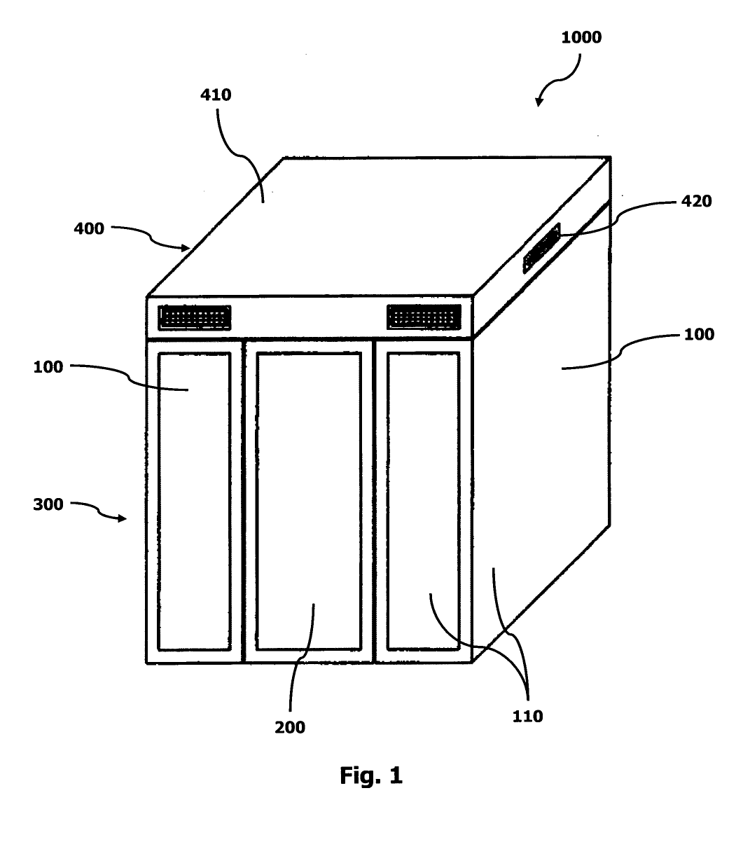

FIG. 1 depicts an electronic equipment housing 1000 having a lower housing base 300 comprising two equipment units 100 and a conditioning unit 200. An upper housing plenum 400 having an upper surface 410 is mounted on top of the lower housing base 300, so as to cover and engage the equipment units 100 and the conditioning unit 200.

The equipment units 100 are generally rectangular prisms with four peripheral walls 110. The equipment units 100 and the conditioning unit 200 are formed with the same height and depth dimensions, such that the equipment and conditioning units 100, 200 can be arranged flush with one another side-by-side. Vents 420 are provided on side walls of the housing plenum 400 and are selectively operable to allow air to be vented from the housing plenum 400.

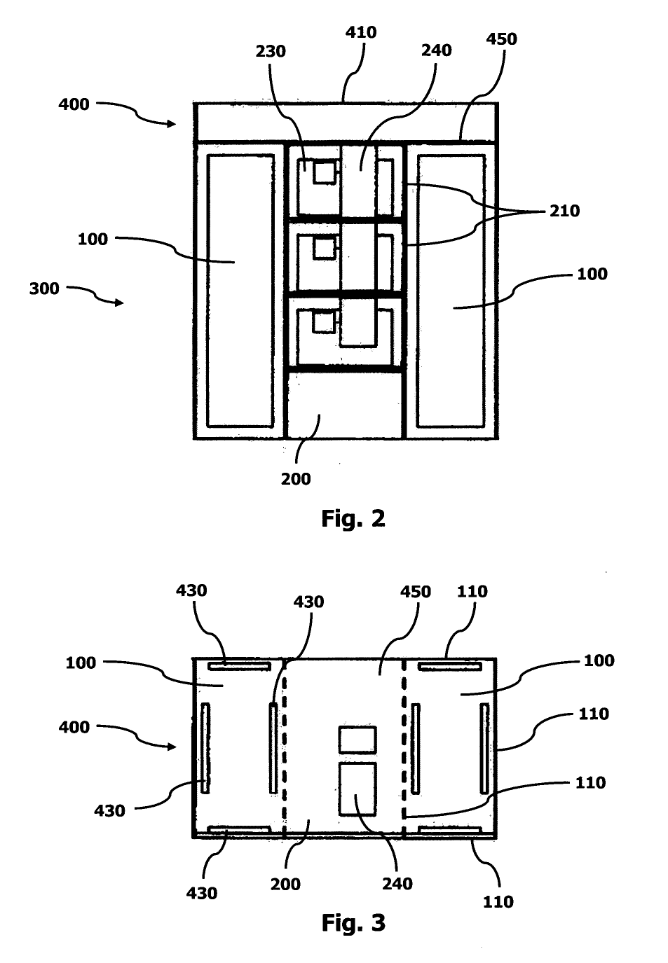

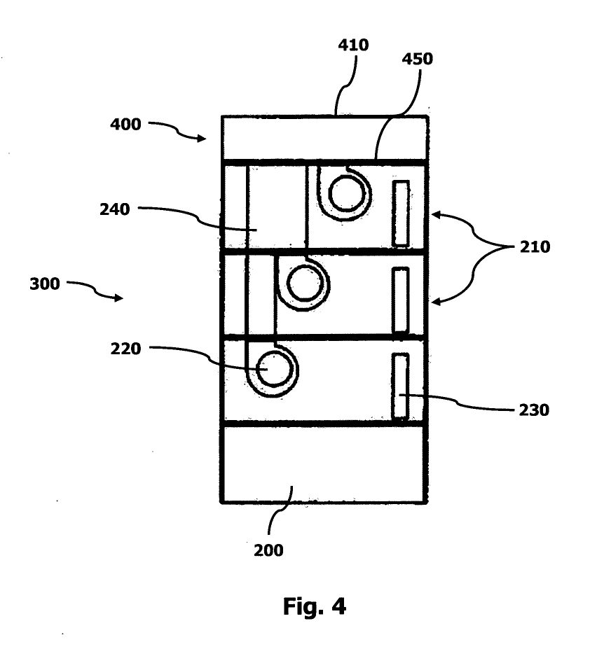

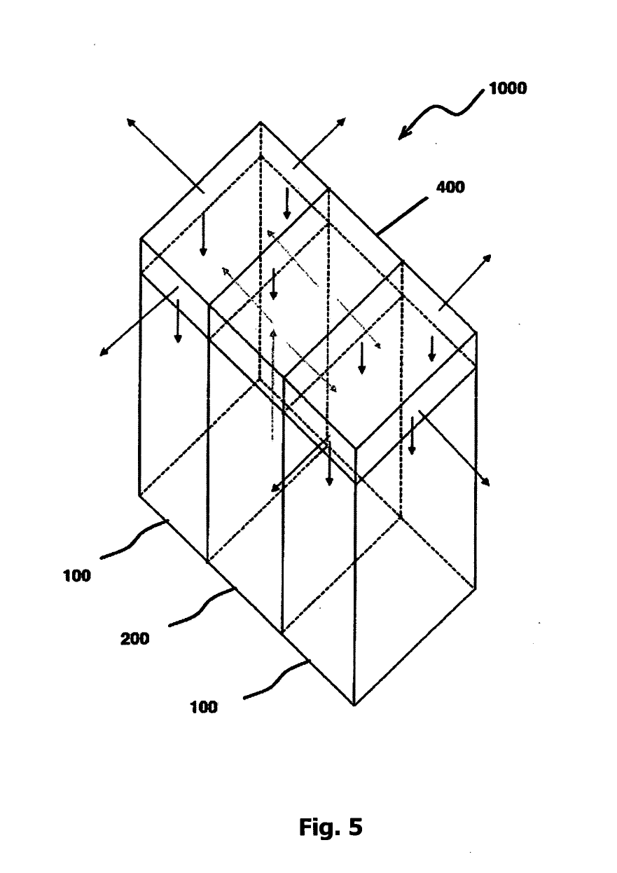

As shown in FIGS. 2 and 4, the conditioning unit 200 houses air conditioners 210, having fans 220, cooling elements 230 and supply ducts 240, for supplying conditioned air to the housing plenum 400.

As shown in FIG. 3, the housing plenum 400 has an array of apertures 430, in the form of elongate slots, formed in a lower surface 450 of the housing plenum 400 above each equipment unit 100. The apertures 430 allow air to pass from the housing plenum 400 directly into the equipment units 100. Each array of apertures 430 includes two pairs of parallel elongate slots located over each equipment unit 100. Each elongate slot 430 is substantially parallel and adjacent to one of the four peripheral walls 110 of the equipment unit 100 directly below the housing plenum 400. The apertures 430 can take any suitable form and may incorporate louvres, which are multi-directional and adjustable.

The equipment and conditioning units 100, 200 are designed to interlock with one another when the electronic equipment housing 1000 is in operation. The equipment and conditioning units 100, 200 can be of any particular dimensions, though are conveniently selected to be of industry-standard dimensions.

The housing plenum 400 engages the equipment units 100 and the conditioning unit 200, securing the housing plenum 400 in place. The housing plenum 400 is in fluid communication with the air conditioners 210 housed in the conditioning unit 200 which are adapted to provide conditioned air into the housing plenum 400. The housing plenum 400 is also in fluid communication via the apertures 430 with the equipment units 100 to deliver conditioned air into the equipment units 100.

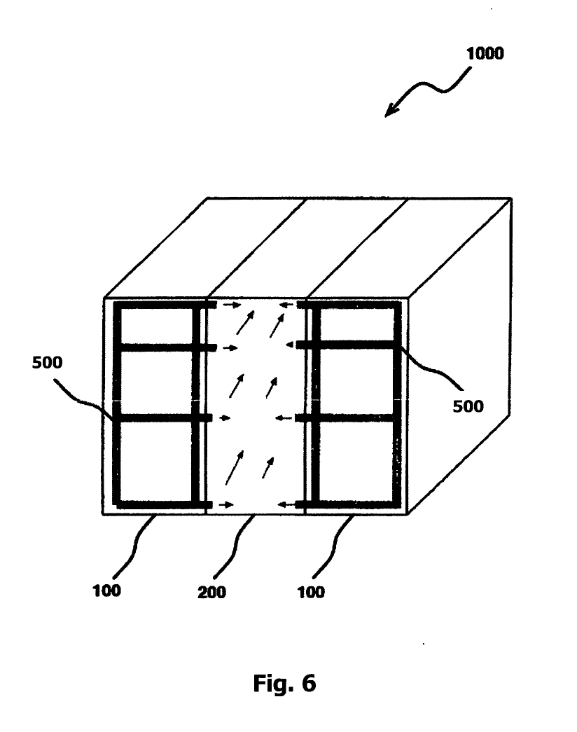

FIG. 5 is a schematic representation of an air circulation pattern for conditioned air generated by the air conditioners 210. This diagram represents the air circulation pattern from the conditioning unit 200, through the housing plenum 400 and into the equipment units 100, with the arrows indicating the direction of air flow.

In operation, conditioned air is discharged vertically up from the conditioning unit 200 under positive pressure into the housing plenum 400. As pressure builds in the housing plenum 400, conditioned air diffuses vertically down through the apertures 430 from the housing plenum 400 into the equipment units 100 flowing down the inside surfaces of the peripheral walls 110 of the equipment units 100. By operation of the vents 420, the air can also be allowed to vent through the front, back and side walls of the housing plenum 400. Various types and arrangements of apertures 430 can be provided in the housing plenum 400 to facilitate this air diffusion pattern, as is apparent to one skilled in the art. The use of adjustable diagonal louvres can be adopted, for example.

The vents 420 provided on the housing plenum 400 are adapted to control air diffusion into the equipment room from the housing plenum 400 and are multidirectional and adjustable. Desirably, the vents 420 can be any suitable construction, and can be shut down to prevent diffusion from the housing plenum 400. Air balancing dampers (not shown) can be installed to balance air flow through the housing plenum 400.

FIG. 6 is a schematic representation of air circulation patterns drawn under negative pressure from the equipment units 100 to the air conditioner in the conditioning unit 200. The arrows indicate the direction of air flow. A duct arrangement 500 is provided on the equipment units 100 to collect air under negative pressure from the equipment units 100. Typically, air is exhausted from the equipment units 100 using an incorporated fan located at the rear of the equipment unit 100. This exhausted air is collected through inlets or perforations in the duct arrangement 500 and returned to the air conditioners in the conditioning unit 200.

Collecting exhausted air in this way reduces the amount of heated air that re-enters the electrical equipment to be further heated due to operation of the electrical equipment. Further, the heat that is exhausted from the equipment and discharged into the equipment room is minimised. Desirably, the duct arrangement is provided with inlets or perforations closely aligned with exhausted air outlets on the electronic equipment to thereby increase the uptake of exhausted air back to the conditioning unit. Use of a duct arrangement 500 in the manner described provides particular performance benefits as, in effect, heat is trapped at its source rather than heating the equipment units 100 and the entire equipment room.

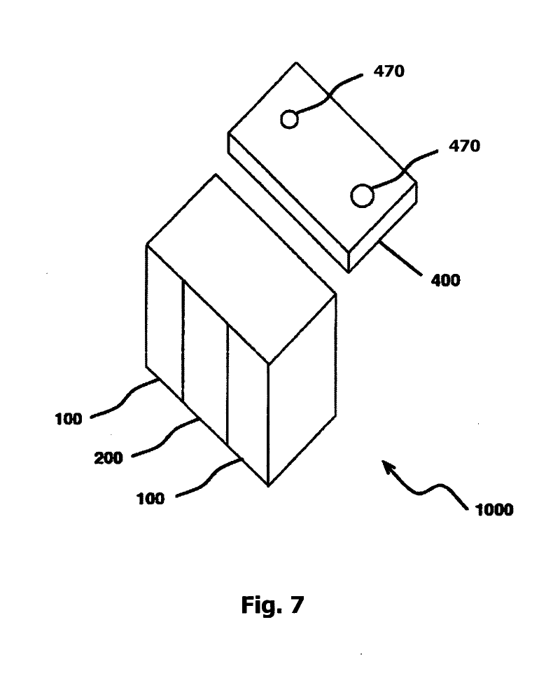

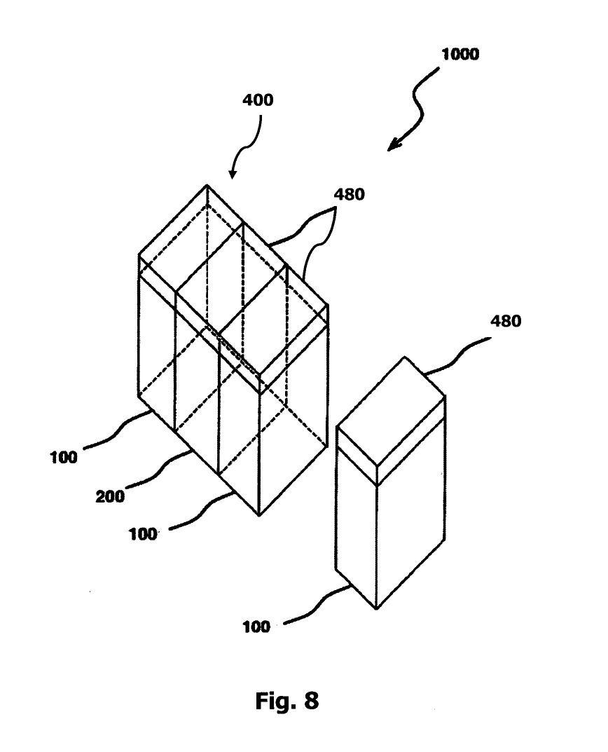

FIG. 7 is a schematic representation of an alternative embodiment of an electronic equipment housing 1000 having a housing plenum 400 that includes optional spigot holes 470 so that the housing plenum 400 can engage with external ducting (not shown). The spigot holes 470 can be provided in any suitable diameter to engage with external ducting (not shown). Typical dimensions may range from a diameter of, say, 150 mm to 450 mm. One application is the installation of ducting directed from the spigots 470 to other parts of the equipment room where conditioned air can be used to ventilate and cool stand-alone equipment, not housed within the electrical equipment housing 1000. The external ducting may be connected through a ceiling cavity in a ceiling space above the equipment room. The external ducting can alternatively be connected to a ceiling air diffuser with a downward vertical flow pattern or a horizontal air diffusion pattern. The external ducting attached to the spigots 470 can also be connected to other areas within the equipment room. For example, side wall registers can be used for distribution of air from the external ducts.

In certain embodiments, the housing plenum 400 can be installed as a unitary construction for the entire lower housing base 300, covering all of the equipment and conditioning units 100, 200.

Alternatively, as best shown in FIG. 10, the housing plenum 400 can be of modular construction and formed by multiple modular plenum units 480, having mating passages or recessed ports 490 to allow air to pass through the housing plenum 400. Additional equipment units 100 are added together with additional plenum units 480 to create an electronic equipment housing 1000 of desired size. In the embodiment depicted, the electronic equipment housing includes six equipment units 100 and three plenum units 480. The modular and integrated constructions provide equivalent air circulation patterns, and modular construction may be favoured to reasons of convenience.

FIG. 8 is a schematic representation of the modular construction of an alternative embodiment of the electronic equipment housing 1000 using modular components. In the so modular embodiment of the electronic equipment housing 1000, the housing plenum 400 consists of multiple modular plenum units 480. Additional equipment units 100 and plenum units 480 can be added to the electronic equipment housing 1000 as would be apparent to one skilled in the art. There is no inherent limit to the number of additional equipment units 100 and plenum units 480 that can be added, rather the practical limiting factor is the cooling capacity of the air conditioners 210, which may range from, say, 9 kW to 60 kW. With additional equipment units 100, a modular construction for the housing plenum 400 is preferred for ease of installation and adaptability. When further equipment units 100 are added, components of the duct arrangement 500 interlock so that air from the additional equipment units 100 is returned via the duct arrangement 500.

The air conditioners 210 in the conditioning unit 200 can be of any suitable construction. A first variation comprises a fully self-contained unit. There are two cooling elements 230, and each cooling element 230 operates independently of each other. Each cooling element 230 is connected to an independent external condensing unit, which is air-cooled. There are, in effect, two independent operating systems, which operate on a direct expansion system using refrigeration gas. A second variation uses chilled water coils. There are two chilled water coils connected to a liquid chiller. The chiller unit is either air-cooled or water-cooled. The air-cooler chiller unit uses condenser water as a medium for condensation of refrigeration gas. The water-cooled chiller unit uses air as a medium for condensation of hot discharge gas. A third variation uses a water-cooled package system. The condenser shell and tube is located inside the conditioning unit 200, with the cooling coils. The coils operate independently on a direct expansion principle using refrigeration gas.

All three of the described variations comprise a centrifugal fan (or multiple fans) inside the conditioning unit 200. This fan draws air across the cooling coils located towards the back of the conditioning unit 200. The fan then discharges cooled air into the housing plenum 400 as described above. The conditioning unit 200 has its own condensate pump and drainage system.

A humidifier can also be contained inside the conditioning unit 200. Two different control systems can be used. A first system is controlled from a central keypad located at the front of the unit. Temperature and humidity is controlled from a digital display. A temperature set point can be adjusted from this fully integrated control keypad. Alternatively, each system can be controlled from two independent microprocessor controllers to regulate both humidity and temperature. A display at the front of the equipment unit 200 indicates current temperature and humidity.

The electronic equipment housing 1000 can also be configured to be remotely controlled, for example, via a web-based interface. Such a management system can incorporate fault management features to log data, monitor irregular operating conditions, such as when temperature or humidity exceeds specified bounds, and send alarms upon failure or irregular operating conditions. Management can be via mircoprocessor or direct digital control (DDC), or a combination of both; also, a backup control system may be provided.

The electronic equipment housing 1000 can be adapted to be installed with existing customer equipment units, though desirably, the customer orders the electronic equipment housing 1000 complete with equipment units 100 to avoid any difficulties that may arise at on-site installation. As equipment units 100 are specified in standard dimensions and fittings, customers can order a electronic equipment housing 1000 that the customer is assured will accept their existing electronic equipment.

The equipment and conditioning units 100, 200 are preferably constructed to industry-standard dimensions. As an alternative to mounting a housing plenum 400 directly upon the equipment and conditioning units 100, 200, the housing plenum 400 can instead be effectively integrated within the equipment and conditioning units 100, 200. As an example, blanking plates can be installed inside the equipment and conditioning units 100, 200. If an equipment or conditioning unit 100, 200 is 2154 mm in height, blanking plates can be installed at a height of say 1804 mm to 1900 mm.

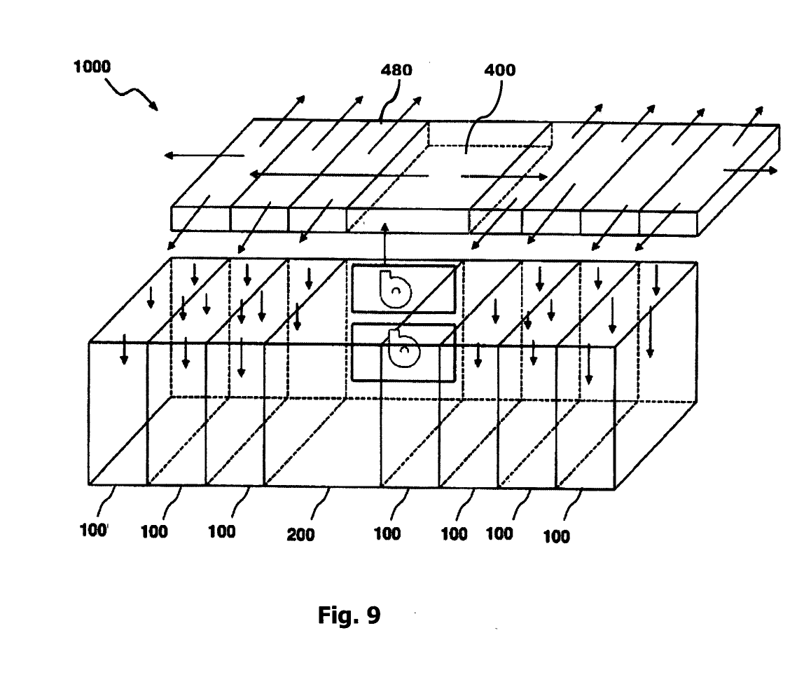

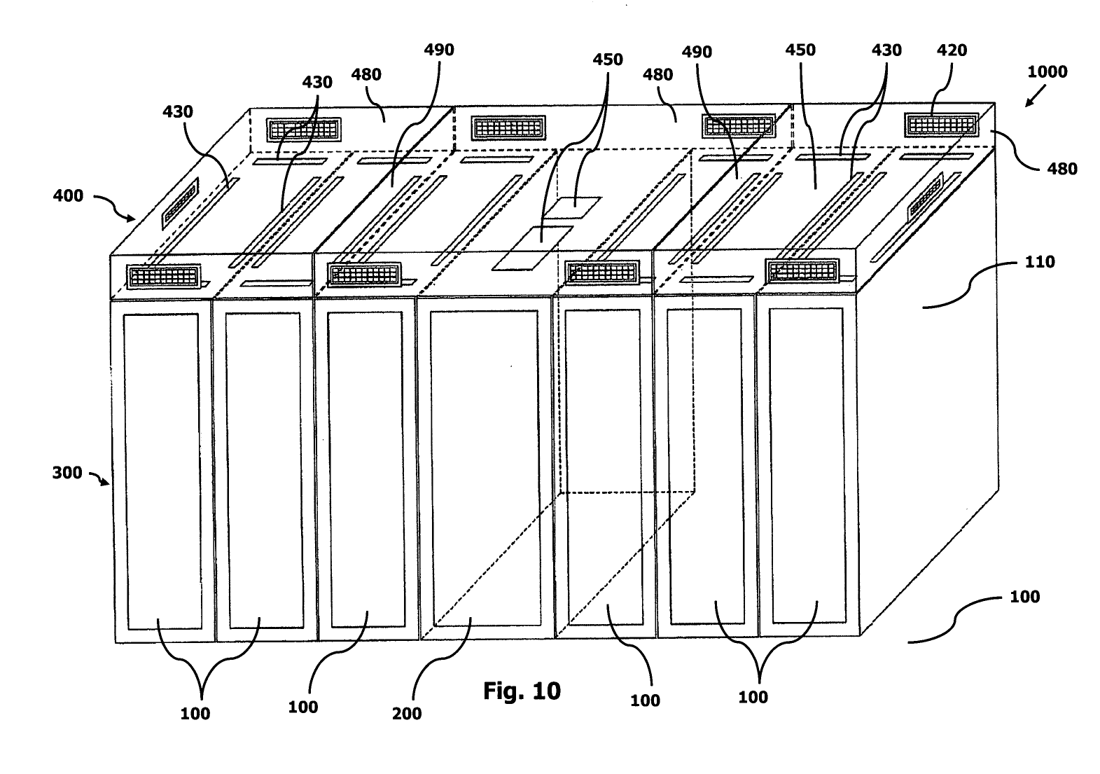

FIG. 9 is a schematic representation of an embodiment of a high-capacity modular electronic equipment housing 1000. As represented, the housing 1000 uses “double” conditioning and equipment units 100, 200 having a width twice that of the more usual dimensions shown in, for example, FIG. 1. The conditioning unit 200 houses an air conditioner having two cooling coils located at the rear of the conditioning unit 200, as with other embodiments described herein. Two centrifugal fans deliver conditioned air to the housing plenum 400. A number of additional equipment units 100 can be incorporated as described above with reference to the modular embodiment. This high-capacity electronic equipment housing 1000 is intended for high-density data centres. In this case, the cooling coils operate either as chilled water coils or direct expansion coils, or a combination of chilled water and direction expansion.

Although the electronic equipment housing 1000 has been described with reference to a specific example, it will be appreciated by those skilled in the art that the housing 1000 may be embodied in many other forms while providing the function and benefits of the example described herein.

1. An electronic equipment housing comprising:
a lower housing body comprising a conditioning unit and an equipment unit, the conditioning unit housing an air conditioner and the equipment unit being adapted to house electrical equipment;
an upper housing plenum mounted on top of the lower housing body, so as to cover and engage the equipment unit, the housing plenum having an upper surface and a lower surface and at least one aperture formed in the lower surface, wherein the aperture is adapted to allow air to pass from the housing plenum directly into the equipment unit and wherein the housing plenum is in fluid communication with the air conditioner; and
a duct arrangement providing fluid communication between the equipment unit and the air conditioner, wherein the duct arrangement is adapted to return air from the equipment unit to the air conditioner;
wherein the air conditioner is adapted to supply conditioned air under positive pressure into the housing plenum, resulting in the flow of conditioned air into the equipment unit via the aperture.

2. The electronic equipment housing of claim 1, wherein the at least one aperture is an elongate slot.

3. The electronic equipment housing of claim 2, wherein the elongate slot is arranged adjacent to a peripheral wall of the equipment unit.

4. The electronic equipment housing of claim 3, wherein the elongate slot is part of an array including two pairs of parallel elongate slots.

5. The electronic equipment housing of claim 4, wherein the equipment unit has four peripheral walls and each elongate slot extends substantially parallel to and adjacent to one of the peripheral walls of the equipment unit.

6. The electronic equipment housing of any one of the preceding claims, wherein the housing plenum is mounted so as to cover and engage both the equipment unit and the conditioning unit.

7. The electronic equipment housing of any one of the preceding claims, comprising multiple equipment units.

8. The electronic equipment housing of claim 7, wherein the housing plenum covers and engages all of the equipment units.

9. The electronic equipment housing of claim 8, wherein the housing plenum is modular and formed from multiple plenum units and wherein additional plenum units and additional equipment units are adapted to be added to the electronic equipment housing to increase the storage capacity of the electronic equipment housing.

10. The electronic equipment housing of claim 9, wherein the plenum units are provided with elongate ports, such that the elongate ports of adjacent plenum units align to allow fluid communication between the adjacent plenum units.

11. The electronic equipment housing of any one of the preceding claims, wherein the housing plenum further includes outlet vents for venting conditioned air from the housing plenum.

12. The electronic equipment housing of any one of the preceding claims, wherein electronic equipment is arranged in the equipment unit and wherein multiple said apertures direct conditioned air into the equipment unit such that the conditioned air is directed down walls of the equipment unit in peripheral air curtains around the electronic equipment in the equipment unit.

13. The electronic equipment housing of any one of the preceding claims, wherein electronic equipment is arranged in the equipment unit and the duct arrangement has inlets positioned directly proximate to outlets for air exhausted from the electronic equipment so that diffusion of air exhausted from the electronic equipment throughout the equipment unit is minimised.

14. An electronic equipment housing substantially as hereinbefore described with reference to any one embodiment, as that embodiment is depicted in the accompanying representations.
